(19) United States
(12) Patent Application Publication
(10) Pub. No.: US 2024/0037310 A1
(43) Pub. Date: Feb. 1, 2024

(54) METHOD, APPARATUS, AND COMPUTER-READABLE STORAGE MEDIUM FOR LAYOUT GENERATION

(71) Applicant: Alibaba Damo (Hangzhou) Technology Co., Ltd., Hangzhou, Zhejiang (CN)

(72) Inventors: Jianjun CHEN, Hangzhou (CN); Tian XIA, Hangzhou (CN); Feng WU, Beijing (CN); Hsiang-Sheng KU, Hangzhou (CN); Huihai ZHAO, Beijing (CN)

(21) Appl. No.: 18/347,177

(22) Filed: Jul. 5, 2023

(30) Foreign Application Priority Data
Jul. 26, 2022 (CN) 202210881462.3

(51) Int. Cl. G06F 30/392

(52) U.S. Cl. CPC G06F 30/392

(57) ABSTRACT

A layout generation method includes: determining a quantum device type; acquiring an original script corresponding to the quantum device type, wherein a device parameter is defined in the original script; acquiring a target value of the device parameter; assigning the target value to the device parameter to obtain a target script of a target quantum device corresponding to the quantum device type; and generating, based on the target script, a quantum chip layout including the target quantum device.

### CROSS-REFERENCE TO RELATED APPLICATIONS

The disclosure claims the benefits of priority to Chinese Application No. 202210881462.3, filed Jul. 26, 2022, which is incorporated herein by reference in its entirety.

### TECHNICAL FIELD

The present disclosure relates to quantum chip layout design, and more particularly, to a method, an apparatus, and a computer-readable storage medium for layout generation.

### BACKGROUND

In a process of layout design of quantum chips, a large number of operations need to be completed manually and the operations are cumbersome. Therefore, the efficiency of layout design is very low.

However, there is no effective solution has been proposed yet to improve the efficiency of layout design.

### SUMMARY OF THE DISCLOSURE

Embodiments of the present disclosure provide a layout generation method. The method includes: determining a quantum device type; acquiring an original script corresponding to the quantum device type, wherein a device parameter is defined in the original script; acquiring a target value of the device parameter; assigning the target value to the device parameter to obtain a target script of a target quantum device corresponding to the quantum device type; and generating, based on the target script, a quantum chip layout including the target quantum device.

Embodiments of the present disclosure provide an apparatus includes a memory configured to store instructions; and one or more processors configured to execute the instructions to cause the apparatus to perform operations for layout generation. The operations include: determining a quantum device type; acquiring an original script corresponding to the quantum device type, wherein a device parameter is defined in the original script; acquiring a target value of the device parameter; assigning the target value to the device parameter to obtain a target script of a target quantum device corresponding to the quantum device type; and generating, based on the target script, a quantum chip layout including the target quantum device.

Embodiments of the present disclosure provide a non-transitory computer-readable storage medium that stores a set of instructions that is executable by one or more processors of an apparatus to cause the apparatus to perform operations including: determining a quantum device type; acquiring an original script corresponding to the quantum device type, wherein a device parameter is defined in the original script; acquiring a target value of the device parameter; assigning the target value to the device parameter to obtain a target script of a target quantum device corresponding to the quantum device type; and generating, based on the target script, a quantum chip layout including the target quantum device.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 is a block diagram of a hardware structure of an exemplary computer terminal for implementing a layout generation method, according to some embodiments of the present disclosure.

FIG. 2 is a flow chart of a first layout generation method, according to some embodiments of the present disclosure.

FIG. 3 is a flow chart of a second layout generation method, according to some embodiments of the present disclosure.

FIG. 4 is a flow chart of another layout generation method, according to some embodiments of the present disclosure.

FIG. 5 is a structural block diagram of a first layout generation apparatus, according to some embodiments of the present disclosure.

FIG. 6 is a structural block diagram of a second layout generation apparatus, according to some embodiments of the present disclosure.

FIG. 7 is a structural block diagram of an exemplary computer terminal, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

A superconducting quantum chip layout is a design drawing of a superconducting quantum chip, which is a result of a quantum chip design stage and, at the same time, a starting point for quantum chip processing. Quantum energy levels of superconducting bits and electromagnetic field distribution that need to be considered in the design stage are finally reflected on the layout. Process engineers perform photolithography, deposition, and other processing processes according to the layout, and finally complete a quantum chip. Test engineers perform measurement activities based on information provided by the layout.

A quantum device in a superconducting quantum chip specifically refers to superconducting quantum bits. Superconducting quantum bits use a quantum effect of a Josephson junction to form a quantum circuit together with a capacitor and an inductor. Under an extremely low temperature condition, the quantum circuit exhibits a quantum effect, which meets the principle of quantum state superposition and the quantum measurement theory.

According to some embodiments of the present disclosure, a layout generation method is provided. It should be noted that steps shown in the flow chart of the drawing may be performed in a computer system such as a set of computer-executable instructions. Although a logical order is shown in the flow chart, in some embodiments, the steps shown or described may be performed in an order different from that shown or described herein.

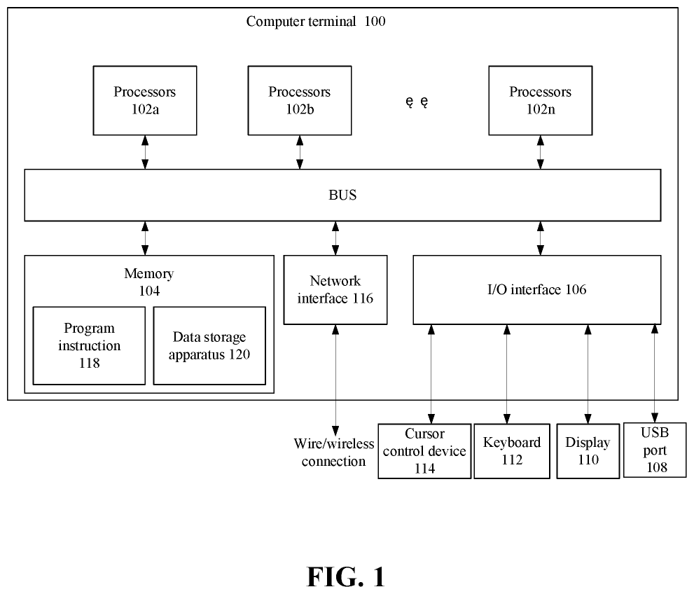

The method provided in the embodiments of the present disclosure may be performed in a mobile terminal, a computer terminal, or a similar computing device. FIG. 1 is a block diagram of a hardware structure of a computer terminal (or a mobile device) for implementing a layout generation method. As shown in FIG. 1, a computer terminal 100 (or a mobile device) may include one or more processors (e.g., 102a, 102b, . . . , 102n), a memory 104 configured to store data, and a transmission apparatus having a communication function. The processor may include, but is not limited to, a processing apparatus such as a microprocessor, a microcontroller unit (MCU), or a programmable logic device, for example a Field-Programmable Gate Array (FPGA). Computer terminal 100 may also include: an input/output interface (I/O interface) 106, a universal serial bus (USB) port 108 (which may be included as one of ports of a BUS), a display 110, a keyboard 112, a cursor control device 114, a network interface 116, a power supply (not shown), or a camera (not shown). Those of ordinary skill in the art can understand that the structure shown in FIG. 1 is merely schematic, and is not intended to limit the structure of the above electronic apparatus. For example, computer terminal 100 may include more or fewer components than those shown in FIG. 1 or have a configuration different from that shown in FIG. 1.

It should be noted that the one or more processors or other data processing circuits described above may generally be referred to herein as a “data processing circuit.” The data processing circuit may be implemented in whole or in part as software, hardware, firmware, or other arbitrary combinations. In addition, the data processing circuit may be a single independent processing module, or be fully or partially integrated into any of the other elements in computer terminal 100 (or mobile device). As mentioned in the embodiments of the present disclosure, the data processing circuit is configured as a processor.

Memory 104 may be configured to store a software program of application software or a module, for example, a program instruction 118 or a data storage apparatus 120 corresponding to the layout generation method in the embodiments of the present disclosure. The one or more processors 102a-n run the software program and module stored in memory 104, to execute various function applications and perform data processing, for example, implement a layout generation method. Memory 104 may include a high-speed random-access memory, and may further include a non-volatile memory, for example, one or more magnetic storage apparatuses, flash memories, or other non-volatile solid-state memories. In some embodiments, memory 104 may further include memories remotely arranged with respect to the processor, and the remote memories may be connected to computer terminal 100 through a network. The example of the network includes, but is not limited to, the Internet, an Intranet, a local area network, a mobile telecommunications network, and a combination thereof.

The transmission apparatus is configured to receive or send data via a network. An example of the network may include a wireless network provided by a communications provider of computer terminal 100. In an example, the transmission apparatus includes a Network Interface Controller (NIC), which may be connected to another network device via a base station to communicate with the Internet. In another example, the transmission apparatus may be a Radio Frequency (RF) module, which is configured to communicate with the Internet in a wireless manner.

Display 110 may be, for example, a touchscreen liquid crystal display (LCD). The LCD may enable a user to interact with a user interface of computer terminal 100 (or mobile device).

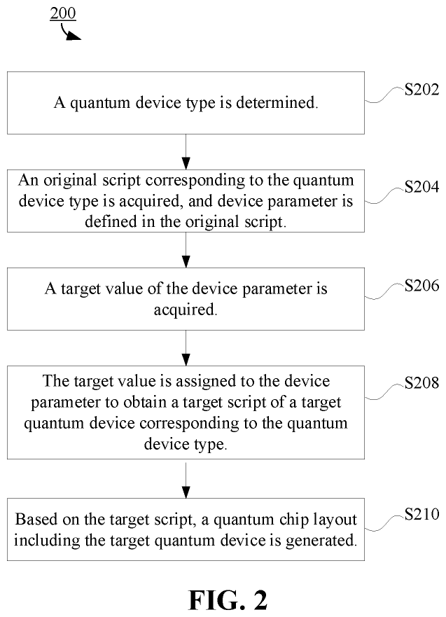

In the above running environment, embodiments of the present disclosure provide a layout generation method. FIG. 2 is a flow chart of a first layout generation method 200, according to some embodiments of the present disclosure. As shown in FIG. 2, method 200 includes steps S202 to S210.

At step S202, a quantum device type is determined.

In some embodiments, the determining a quantum device type includes: acquiring a fuzzy structure of a quantum device; and determining the quantum device type based on the fuzzy structure. In this example, the quantum device type may be determined in different ways. For example, the quantum device type may be acquired directly. If the quantum device type cannot be directly determined, a fuzzy structure of the quantum device may be determined first, and then the quantum device type is determined according to the fuzzy structure. For example, data such as inaccurate shape and size of the quantum device provided by the user may be identified. Then a corresponding standard quantum device type can be automatically determined, or several quantum device types that conform to the data may be determined at the same time for the user to choose.

In some embodiments, the above quantum device may include a plurality of types, for example, may include at least one of the following: Fluxonium quantum bits, a quantum port, a ground plane, a coplanar waveguide, and a quantum component constructed based on Fluxonium quantum bits. The quantum component constructed based on the Fluxonium quantum bits may be a quantum bit gate constructed based on the Fluxonium quantum bits, and the like.

At step S204, an original script corresponding to the quantum device type is acquired, and device parameter is defined in the original script.

In some embodiments, the acquiring an original script corresponding to the quantum device type includes: acquiring a general-purpose script, wherein a type parameter of a device type is defined in the general-purpose script; and assigning the quantum device type to the type parameter to obtain the original script corresponding to the quantum device type. In order to improve the efficiency of generating the quantum chip layout and enhance the applicability of generating the quantum chip layout, a type parameter for defining a device type may be added on the basis of a general-purpose script, so that by adjusting the type parameter, original scripts corresponding to different types may be obtained according to general-purpose script. That is, different types of quantum devices may be generated by using different original scripts, which greatly improves the efficiency of layout generation. Therefore, not only can the target script be generated directly with the original script, where the user does not need professional script knowledge, but also can the original script be generated in the form of the general-purpose script. That is, an original script may be acquired by using a ready-made script, which effectively eliminating the professional requirements of scripts for the user.

At step S206, a target value of the device parameter is acquired.

In some embodiments, when the target value of the device parameter is acquired, the device parameter may include a plurality of types of device parameters. For example, the device parameter may be a geometric parameter or an action parameter. Therefore, in a case that the device parameter includes the geometric parameter and the action parameter, when acquiring the target value of the device parameter, the following manner may be adopted: determining a geometric parameter type included in the geometric parameter and an action parameter type included in the action parameter respectively; acquiring a geometric parameter value corresponding to the geometric parameter type and an action parameter value corresponding to the action parameter type respectively; and using the geometric parameter value and the action parameter value as the target value. The geometric parameter may be used for setting geometric information such as the shape and size of the quantum device. The geometric parameter includes a plurality of types of geometric parameters, for example, length, width, thickness, plane, curved surface, and the like. The action parameter may be used for setting an editing action for the quantum device, and the action parameter may also include a plurality of types of action parameters, for example, moving, rotating, and the like. By combining the geometric parameter and the action parameter to set and adjust the size or the editing action of the quantum device, the quantum device can be determined more accurately, and the accuracy of generating the quantum chip layout can be improved.

At step S208, the target value is assigned to the device parameter to obtain a target script of a target quantum device corresponding to the quantum device type.

At step S210, based on the target script, a quantum chip layout including the target quantum device is generated.

In some embodiments, when there are a plurality of quantum device types, the plurality of quantum device types correspond to a plurality of target quantum devices. The generating, based on the target script, a quantum chip layout including the target quantum device includes: acquiring an arrangement relationship between the plurality of target quantum devices; and generating, based on target scripts of the plurality of target quantum devices and the arrangement relationship, a quantum chip layout including the plurality of target quantum devices. After determining all the quantum device types contained in the quantum chip, an arrangement relationship of various quantum devices in the quantum chip further needs to be acquired. The arrangement relationship includes positions, relative positions, connection relationships, and the like of various quantum devices. Based on the target scripts corresponding to the various quantum device types and the above arrangement relationship, the quantum chip can be determined. That is, the quantum chip layout can be generated by using the target script and the arrangement relationship of the quantum device. It should be noted that there may be a plurality of quantum devices corresponding to each of the plurality of quantum device types, that is, there are a plurality of quantum devices of the same type.

In some embodiments, the generating, based on the target script, a quantum chip layout including the target quantum device includes: creating a target macro based on the target script, wherein the target macro is used for batch-generating other scripts of a plurality of other quantum devices of the same type as the target quantum device and the other scripts have adjustable device parameters; and generating, based on the target script and the target macro, the quantum chip layout including the target quantum device and the other quantum devices. If there are some quantum devices in quantum chips that need to be frequently used in batches, in order to improve the efficiency of quantum chip layout generation, target macros may be created based on target scripts for these quantum devices, and then corresponding scripts for a certain type of quantum devices may be generated in batches by using the target macros, thereby avoiding the trouble of repeatedly determining the quantum device type. In addition, the target macro may be created not only by a single quantum device, but also by a substructure composed of a plurality of quantum devices. As long as the substructure needs to be reused in the layout, the efficiency of layout generation may be improved by creating the target macro.

In some embodiments, the generating, based on the target script and the target macro, the quantum chip layout including the target quantum device and the other quantum devices includes: acquiring parameter values of the plurality of other quantum devices; assigning the parameter values to device parameters of the corresponding other quantum devices through a parameter modification interface of the target macro, and batch-generating other scripts of the plurality of other quantum devices; and generating, based on the target script and the other scripts, the quantum chip layout including the target quantum device and the other quantum devices. When using the target macro to batch-generate scripts for quantum devices, a parameter modification interface of the target macro may be used to batch-adjust specific parameters in the script that needs to be generated. For example, a plurality of sets of device parameters are batch-set in the target macro, each set of device parameters corresponding to a quantum device to be generated. By using this method to determine the script corresponding to the quantum device, on the one hand, scripts corresponding to a plurality of quantum devices may be obtained by using scripts in a high efficiency; and on the other hand, flexibility and accuracy in adjusting various parameters in the script are ensured.

With the above steps, a script is used. First a quantum device type for which layout generation is to be performed is determined, and based on the quantum device type, an original script corresponding to the type is determined. Then, according to actual application requirements, a value of the quantum device parameter is acquired, and a device parameter in the original script is assigned according to a target value of the parameter to obtain a target script. Then the target script is used to directly generate the required quantum chip layout, thereby achieving the objective that a user does not need to master professional scripts to generate the required quantum chip layout, so that technical problem that the layout design of quantum chips is cumbersome in operation and low in efficiency is resolved and the generation efficiency of the quantum chip layout is effectively improved.

In some embodiments, after generating the quantum chip layout by using the target script, the quantum chip layout may be modified or adjusted directly by adjusting the parameter in the script. The accuracy of directly adjusting the parameter is much higher than that of adjusting the layout by manually dragging in the related technology, thereby avoiding a large number of tedious manual operations in the design process of quantum chip layout and improving the efficiency of layout design.

In some embodiments, after generating, based on the target script, a quantum chip layout including the target quantum device, the method further includes: receiving a script verification request, wherein the script verification request carries a label of a quantum device requesting verification; determining, based on the label, a to-be-verified script corresponding to the quantum device requesting verification; and extracting the to-be-verified script and verifying the to-be-verified script to obtain a verification result. Different quantum devices may have different labels set accordingly, and by setting the labels. Parts that need to be edited or verified may be quickly determined, thereby achieving efficient and accurate modification or adjustment of some quantum devices in the circuit. Each independent quantum device in the layout has a unique label, which corresponds to an independent script. The corresponding script may be found through label lookup, and the script may be independently verified. The composition and position of the corresponding quantum device may be determined through script verification to determine whether it is a quantum device in the layout to be generated, for example, whether the corresponding type, corresponding function, and other information are accurate. It should be noted that labels may adopt various naming rules, and the labels of various quantum devices may be set in various manners. For example, in the process of generating a script corresponding to a quantum device, a label may be automatically generated based on the script generation time and order, type, and various parameters of the quantum device. The user may also set labels of various quantum devices voluntarily, and so on.

In some embodiments, after generating a quantum chip layout including the target quantum device, various methods may be used to output and display the quantum chip layout. For example, the following methods may be used: receiving a layout drawing instruction; and calling, in response to the layout drawing instruction, a third-party drawing application to draw the quantum chip layout. It should be noted that the third-party drawing application mentioned above may be of various types, such as commonly used CAD drawing software or Mypaint drawing software.

In some embodiments, an existing layout can be directly imported into the current layout. For this part, various quantum devices in the imported part may be determined through manual labeling or automatic recognition, and then the imported layout may be directly applied.

In some embodiments, simulation or Hamiltonian calculation can be performed based on the generated quantum chip layout, and the quantum chip layout can be efficiently and accurately adjusted through label selection and parameter modification based on a simulation result or calculation result.

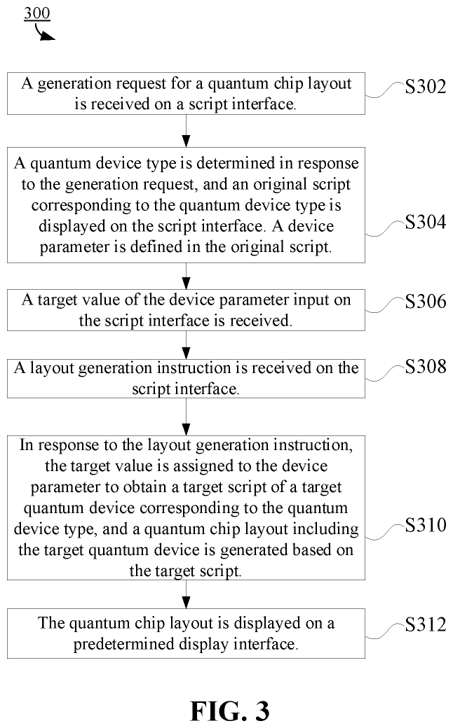

FIG. 3 is a flow chart of a second layout generation method 300, according to some embodiments of the present disclosure. As shown in FIG. 3, method 300 includes steps S302 to S312.

At step S302, a generation request for a quantum chip layout is received on a script interface.

At step S304, a quantum device type is determined in response to the generation request, and an original script corresponding to the quantum device type is displayed on the script interface. A device parameter is defined in the original script.

At step S306, a target value of the device parameter input on the script interface is received.

At step S308, a layout generation instruction is received on the script interface.

At step S310, in response to the layout generation instruction, the target value is assigned to the device parameter to obtain a target script of a target quantum device corresponding to the quantum device type, and a quantum chip layout including the target quantum device is generated based on the target script.

At step S312, the quantum chip layout is displayed on a predetermined display interface.

By performing the above operations, a script may be used to gradually determine, according to a generation request, a quantum device type for which layout generation is to be performed. Based on the quantum device type, an original script corresponding to the type is determined. Then, according to actual application requirements, a parameter value of the quantum device is acquired, and a device parameter in the original script is assigned according to a target value of the parameter to obtain a target script. Therefore, a user does not need to master professional scripts to generate the required quantum chip layout and the quantum chip layout can be displayed on a predetermined display interface, thereby solving the technical problem that the layout design of quantum chips is cumbersome in operation and low in efficiency, and effectively improving the generation efficiency of the quantum chip layout.

In some embodiments, after generating the quantum chip layout by using the target script, the quantum chip layout may be modified or adjusted directly by adjusting the parameter in the script, and the accuracy of directly adjusting the parameter is much higher than that of adjusting the layout by manually dragging in the related technology, thereby achieving the technical effect of avoiding a large number of tedious manual operations in the design process of quantum chip layout and improving the efficiency of layout design, thereby solving the technical problem that the layout design of quantum chips is cumbersome in operation and low in efficiency.

Based on the foregoing embodiments, the present disclosure provides an implementation method, which will be described below.

Currently, the layout design of quantum chips lacks convenient and efficient design tools, and device generation, arrangement, error correction, and other operations in the process need to be completed manually, which is not intelligent enough, and manual operations are cumbersome and inefficient.

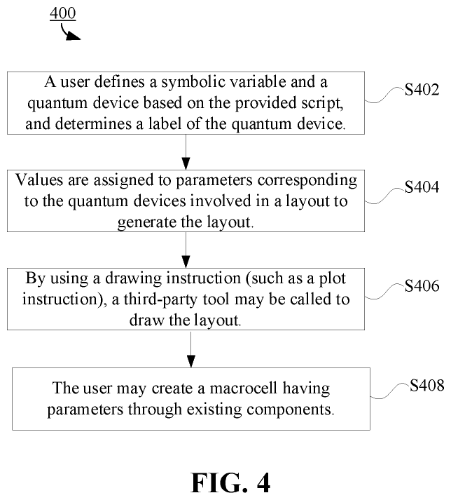

In response to the above technical issues, some embodiments of the present disclosure propose a layout generation method, and the method can complete circuit simulation and layout design without the need for a user to learn programming languages. By developing a script language, a quantum chip layout is generated, thereby increasing the design flexibility and improving the efficiency of layout generation. FIG. 4 is a flow chart of another exemplary layout generation method 400, according to some embodiments of the present disclosure. As shown in FIG. 4, method 400 includes the steps S402 to S408.

At step S402, a user defines a symbolic variable and a quantum device based on the provided script, and determines a label of the quantum device.

For example, the user may define parameters such as a type and a name of the quantum device. Correspondingly, the type of the quantum device may be defined as “type” in the script (for example, 7 types may be defined), and the name of the quantum device may correspond to “name” in the script.

In addition, when the user defines various parameters of the quantum device, the parameters may be adjustable. An initial parameter may be pre-set, which may be a fixed value or a variable. The parameter may be a basic geometric parameter of the device (such as the length and width of the line), or an action parameter (such as movement and rotation).

An actual definition process of the quantum device is illustrated below.

qubit q_1

End

The above programming language is a process of defining a quantum bit (qubit) called “q_1.” Parameters of the qubit may include a length, a width, a relative position, and line parameters of a capacitor plate. Other types of the quantum device, for example, may also be a port, a ground plane, a coplanar waveguide (cpw), and so on. The adjustable parameters for various quantum devices may be a shape, and changes to the waveguide may include a starting point, an orientation, a radius, a radian, an angle, a length, a width, and the like.

Taking the coplanar waveguide as an example, a characteristic of the coplanar waveguide is that the geometric shape is very flexible, but the width is determined because of the need to maintain a specific impedance. Therefore, in the method of combining the parameters with the action according to the embodiments of the present disclosure, the parameters include a metal line width of the coplanar waveguide and a width of an air slot, and the action includes forwarding and circling. A parameter (such as the distance to forward) needs to be provided to the forwarding; and a parameter (such as the radius and angle of the arc) also needs to be provided to the circling. A skeleton of the coplanar waveguide is formed based on a combination of the two actions, and then in combination with other parameters such as the width of the coplanar waveguide, a metal strip, an air gap, and an outer protective layer of the waveguide are automatically generated. This method provides the user a high degree of freedom in addition to the high efficiency of designing the coplanar waveguide.

At step 404, after various quantum devices are defined, values are assigned to parameters corresponding to the quantum devices involved in a layout to generate the layout.

In a specific implementation process, a standard quantum device may be identified as a target based on an approximate shape of the quantum device provided by the user (such as imprecise length and width), and then values are assigned to parameters of the standard quantum device to determine a quantum device used for generating the layout.

At step S406, by using a drawing instruction (such as a plot instruction), a third-party tool may be called to draw the layout. When making subsequent modification, parameters may be modified at any time to simplify subsequent modification and maintenance.

At step S408, the user may create a macrocell having parameters through existing components.

The macrocell may be used for completing a sub-design structure that is reused more times in the layout. The macrocell is internally composed of predefined devices or smaller macrocells. Relative positions between the components may be expressed by a mathematical formula. In addition, the macrocell may provide a parameter interface, which may be called by an upper layer to obtain a changed structure through parameter assignment.

Parameterized cells can be supported by the embodiments of the present disclosure, and structural forms used in the design repeatedly are designed into parameterized units. An internal structure of the parameterized unit may be adjusted and changed through interface parameters to meet specific needs of different designs. In the design, parameter cell instantiation is utilized to quickly obtain the required and much more complex structure compared to a basic cell. The parameterized cells obtained in previous designs may be organized into a cell library, and the parameterized cells may be iterated and utilized repeatedly in future designs to improve the speed of layout design.

In some embodiments, an independent software can be formed correspondingly to the embodiments of the present disclosure, thereby providing the user with services such as cloud services or plugins of existing software, and providing the user with automatic design and error correction functions.

At the same time, when a component library is developed or a component library is defined by the user, each component may be labeled to calibrate parameters (such as geometric shape, component type, and functional application) in various aspects of the element to facilitate simulation analysis of the generated layout. Simulation calculation may also be performed directly based on labels of various components on the layout to obtain a quantum device composed based on the labeled components, and directly generate the Hamiltonian of the quantum device in the layout based on the quantum device, and the like.

When the user needs to modify, a corresponding part of the script may be called out according to the requirements of the user for editing and verification by the user. For example, when the user makes a fine adjustment to a partial structure in the layout, a parameter script corresponding to an interface may be called out by directly frame-selecting the structure for editing. That is, the modification or adjustment of some devices in all circuits may be realized to achieve the effect of efficient and accurate adjustment.

In some embodiments, an ordinary layout may also be imported into the software mentioned above to become a part of the chip layout. By manually labeling the imported part according to the script component naming rule, a simulation part may identify component types in the imported part of the layout, thereby performing simulation calculation on the layout.

In some embodiments, the parameters of various quantum devices included in the quantum chip can be directly corrected based on the script when the layout of the quantum chip is generated through the script. Compared with directly correcting the generated layout itself, it is more direct and easier.

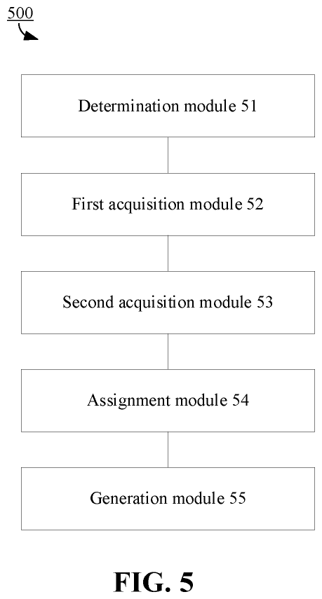

According to the embodiments of the present disclosure, an apparatus for implementing the above layout generation method is further provided. FIG. 5 is a structural block diagram of a first layout generation apparatus 500, according to some embodiments of the present disclosure. As shown in FIG. 5, apparatus 500 includes a determination module 51, a first acquisition module 52, a second acquisition module 53, an assignment module 54, and a generation module 55.

Determination module 51 is configured to determine a quantum device type. First acquisition module 52 is connected to determination module 51 and configured to acquire an original script corresponding to the quantum device type, and a device parameter is defined in the original script. Second acquisition module 53 is connected to first acquisition module 52 and configured to acquire a target value of the device parameter. Assignment module 54 is connected to second acquisition module 53 and configured to assign the target value to the device parameter to obtain a target script of a target quantum device corresponding to the quantum device type. Generation module 55 is connected to assignment module 54 and configured to generate, based on the target script, a quantum chip layout including the target quantum device.

It should be noted that determination module 51, first acquisition module 52, second acquisition module 53, assignment module 54, and generation module 55 correspond to step S202 to step S210 of method 200, and examples and application scenarios implemented by the five modules and the corresponding steps are the same, but are not limited to content disclosed in the method embodiments. It should be noted that the modules can run in the computer terminal 100 provided in the method embodiments as a part of the apparatus.

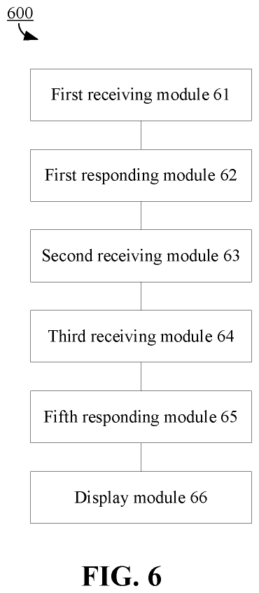

According to the embodiments of the present disclosure, another apparatus for implementing the above layout generation method is further provided. FIG. 6 is a structural block diagram of a second layout generation apparatus 600, according to some embodiments of the present disclosure. As shown in FIG. 6, apparatus 600 includes a first receiving module 61, a first responding module 62, a second receiving module 63, a third receiving module 64, a fifth responding module 65, and a display module 66.

First receiving module 61 is configured to receive a generation request for a quantum chip layout on a script interface. First responding module 62 is configured to determine a quantum device type in response to the generation request, and display an original script corresponding to the quantum device type on the script interface, and a device parameter is defined in the original script. Second receiving module 63 is configured to receive a target value of the device parameter input on the script interface. Third receiving module 64 is configured to receive a layout generation instruction on the script interface. Fifth responding module 65 is configured to assign, in response to the layout generation instruction, the target value to the device parameter, obtain a target script of a target quantum device corresponding to the quantum device type, and generate a quantum chip layout including the target quantum device based on the target script. Display module 66 is configured to display the quantum chip layout on a predetermined display interface.

It should be noted that first receiving module 61, first responding module 62, second receiving module 63, third receiving module 64, fifth responding module 65, and display module 66 correspond to step S302 to step S312 in method 300 and examples and application scenarios implemented by the six modules and the corresponding steps are the same, but are not limited to content disclosed in the method embodiments. It should be noted that the modules can run in the computer terminal 100 provided in the method embodiments as a part of the apparatus.

Embodiments of the present disclosure may provide a computer terminal. The computer terminal may be any computer terminal device in a computer terminal group. In some embodiments, the computer terminal may also be replaced with a terminal device such as a mobile terminal.

In some embodiments, the computer terminal may be located in at least one of a plurality of network devices in a computer network.

In the present disclosure, the above computer terminal may execute program codes of the following steps in a layout generation method of an application: determining a quantum device type; acquiring an original script corresponding to the quantum device type, wherein a device parameter is defined in the original script; acquiring a target value of the device parameter; assigning the target value to the device parameter to obtain a target script of a target quantum device corresponding to the quantum device type; and generating, based on the target script, a quantum chip layout including the target quantum device.

In the present disclosure, the above computer terminal may execute program codes of the following steps in the layout generation method of the application: receiving a generation request for a quantum chip layout on a script interface; determining a quantum device type in response to the generation request, and displaying an original script corresponding to the quantum device type on the script interface, wherein a device parameter is defined in the original script; receiving a target value of the device parameter input on the script interface; receiving a layout generation instruction on the script interface; assigning, in response to the layout generation instruction, the target value to the device parameter to obtain a target script of a target quantum device corresponding to the quantum device type, and generating a quantum chip layout including the target quantum device based on the target script; and displaying the quantum chip layout on a predetermined display interface.

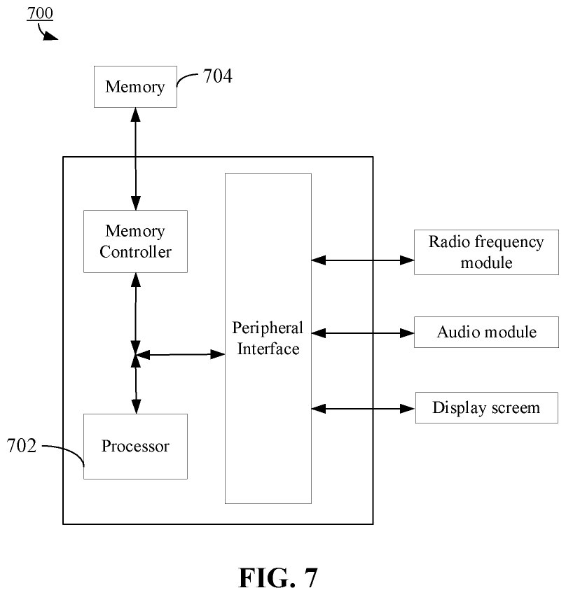

In some embodiments, FIG. 7 is a structural block diagram of a computer terminal 700, according to some embodiments of the present disclosure. As shown in FIG. 7, computer terminal 700 may include: one or more (only one is shown in the figure) processors 702, a memory 704, and the like.

Memory 704 can be configured to store a software program and a module, for example, a program instruction/module corresponding to the layout generation method and apparatus in the embodiments of the present disclosure. Processor 702 runs the software program and module stored in memory 704, to execute various function applications and perform data processing, that is, implement the above layout generation method. Memory 704 can include a high-speed random-access memory, and may further include a non-volatile memory, e.g., one or more magnetic storage apparatuses, a flash memory, or another non-volatile solid-state memory. In some examples, memory 704 may further include memories remotely arranged with respect to the processor, and the remote memories may be connected to the computer terminal through a network. The example of the network includes, but is not limited to, the Internet, an Intranet, a local area network, a mobile telecommunications network, and a combination thereof.

Processor 702 may call information and an application stored in memory 704 through a transmission apparatus to perform the following steps: determining a quantum device type; acquiring an original script corresponding to the quantum device type, wherein a device parameter is defined in the original script; acquiring a target value of the device parameter; assigning the target value to the device parameter to obtain a target script of a target quantum device corresponding to the quantum device type; and generating, based on the target script, a quantum chip layout including the target quantum device.

In some embodiments, processor 702 may further execute program codes of the following steps: acquiring a fuzzy structure of a quantum device; and determining the quantum device type based on the fuzzy structure.

In some embodiments, processor 702 may further execute program codes of the following steps: acquiring a general-purpose script, wherein a type parameter of a device type is defined in the general-purpose script; and assigning the quantum device type to the type parameter to obtain the original script corresponding to the quantum device type.

In some embodiments, processor 702 may further execute program codes of the following steps: determining, when the device parameter includes a geometric parameter and an action parameter, a geometric parameter type included in the geometric parameter and an action parameter type included in the action parameter respectively; and acquiring a geometric parameter value corresponding to the geometric parameter type and an action parameter value corresponding to the action parameter type respectively, and using the geometric parameter value and the action parameter value as the target value.

In some embodiments, when there are a plurality of quantum device types, the plurality of quantum device types correspond to a plurality of target quantum devices, processor 702 may further execute program codes of the following steps: acquiring an arrangement relationship between the plurality of target quantum devices; and generating, based on target scripts of the plurality of target quantum devices and the arrangement relationship, a quantum chip layout including the plurality of target quantum devices.

In some embodiments, processor 702 may further execute program codes of the following steps: creating a target macro based on the target script, wherein the target macro is used for batch-generating other scripts of a plurality of other quantum devices of the same type as the target quantum device and having adjustable device parameters; and generating, based on the target script and the target macro, the quantum chip layout including the target quantum device and the other quantum devices.

In some embodiments, processor 702 may further execute program codes of the following steps: acquiring parameter values of the plurality of other quantum devices; assigning the parameter values to device parameters of the corresponding other quantum devices through a parameter modification interface of the target macro, and batch-generating other scripts of the plurality of other quantum devices; and generating, based on the target script and the other scripts, the quantum chip layout comprising the target quantum device and the other quantum devices.

In some embodiments, processor 702 may further execute program codes of the following steps: receiving a script verification request, wherein the script verification request carries a label of a quantum device requesting verification; determining, based on the label, a to-be-verified script corresponding to the quantum device requesting verification; and extracting the to-be-verified script and verifying the to-be-verified script to obtain a verification result.

In some embodiments, processor 702 may further execute program codes of the following steps: receiving a layout drawing instruction; and calling, in response to the layout drawing instruction, a third-party drawing application to draw the quantum chip layout.

Processor 702 may call information and an application stored in memory 704 through the transmission apparatus to perform the following steps: receiving a generation request for a quantum chip layout on a script interface; determining a quantum device type in response to the generation request, and displaying an original script corresponding to the quantum device type on the script interface, wherein a device parameter is defined in the original script; receiving a target value of the device parameter input on the script interface; receiving a layout generation instruction on the script interface; assigning, in response to the layout generation instruction, the target value to the device parameter to obtain a target script of a target quantum device corresponding to the quantum device type, and generating a quantum chip layout including the target quantum device based on the target script; and displaying the quantum chip layout on a predetermined display interface.

By using the embodiments of the present disclosure, a layout generation solution is provided. A script is used to determine a quantum device type for which layout generation is to be performed. Based on the quantum device type, an original script corresponding to the type is determined. Then, according to actual application requirements, a parameter value of the quantum device is obtained, and a device parameter in the original script is assigned based on a target value of the parameter to obtain a target script, thereby achieving the objective of directly generating a required quantum chip layout by using the target script. At the same time, after generating the quantum chip layout by using the target script, the quantum chip layout may be modified or adjusted directly by adjusting the parameter in the script, and the accuracy of directly adjusting the parameter is much higher than that of adjusting the layout by manually dragging in the related technology, thereby achieving the technical effect of avoiding a large number of tedious manual operations in the design process of quantum chip layout and improving the efficiency of layout design, and thus solving the technical problem that the layout design of quantum chips is cumbersome in operation and low in efficiency.

Those of ordinary skill can understand that the structure shown in FIG. 7 is merely schematic. The computer terminal may also be a terminal device such as a smart phone (such as an Android phone and an iOS phone), a tablet computer, a palmtop computer, a Mobile Internet device (MID), and a Portable Android Device (PAD). FIG. 7 is not intended to limit the structure of the above electronic apparatus. For example, the computer terminal may further include more or fewer components (such as a network interface and a display apparatus) than those shown in FIG. 7, or have a configuration different from that shown in FIG. 7.

Those of ordinary skill in the art may understand that all or a part of steps in various methods of the above embodiments may be implemented by a program instructing hardware related to a terminal device. The program may be stored in a computer-readable storage medium, and the computer-readable storage medium may include: a flash memory, a Read-Only Memory (ROM), a Random Access Memory (RAM), a magnetic disk, or an optical disc.

Embodiments of the present disclosure further provide a computer-readable storage medium. In some embodiments, the computer-readable storage medium may be configured to store program codes executed by the layout generation methods described in the method embodiments.

In some embodiments, the computer-readable storage medium may be located in any computer terminal in a computer terminal group in a computer network, or located in any mobile terminal in a mobile terminal group.

In some embodiments, the computer-readable storage medium is configured to store program codes for performing the following steps: determining a quantum device type; acquiring an original script corresponding to the quantum device type, wherein a device parameter is defined in the original script; acquiring a target value of the device parameter; assigning the target value to the device parameter to obtain a target script of a target quantum device corresponding to the quantum device type; and generating, based on the target script, a quantum chip layout including the target quantum device.

In some embodiments, the computer-readable storage medium is configured to store program codes for performing the following steps: obtaining the fuzzy structure of the quantum device; and determining the type of the quantum device based on the fuzzy structure.

In some embodiments, the computer-readable storage medium is configured to store program codes for performing the following steps: acquiring a general-purpose script, wherein a type parameter of a device type is defined in the general-purpose script; and assigning the quantum device type to the type parameter to obtain the original script corresponding to the quantum device type.

In some embodiments, the computer-readable storage medium is configured to store program codes for performing the following steps: determining, when the device parameter includes a geometric parameter and an action parameter, a geometric parameter type included in the geometric parameter and an action parameter type included in the action parameter respectively; and acquiring a geometric parameter value corresponding to the geometric parameter type and an action parameter value corresponding to the action parameter type respectively, and using the geometric parameter value and the action parameter value as the target value.

In some embodiments, when there are a plurality of quantum device types and the plurality of quantum device types correspond to a plurality of target quantum devices, the computer-readable storage medium is configured to store program codes for performing the following steps: acquiring an arrangement relationship between the plurality of target quantum devices; and generating, based on target scripts of the plurality of target quantum devices and the arrangement relationship, a quantum chip layout including the plurality of target quantum devices.

In some embodiments, the computer-readable storage medium is configured to store program codes for performing the following steps: creating a target macro based on the target script, wherein the target macro is used for batch-generating other scripts of a plurality of other quantum devices of the same type as the target quantum device and having adjustable device parameters; and generating, based on the target script and the target macro, the quantum chip layout including the target quantum device and the other quantum devices.

In some embodiments, the computer-readable storage medium is configured to store program codes for performing the following steps: acquiring parameter values of the plurality of other quantum devices; assigning the parameter values to device parameters of the corresponding other quantum devices through a parameter modification interface of the target macro, and batch-generating other scripts of the plurality of other quantum devices; and generating, based on the target script and the other scripts, the quantum chip layout comprising the target quantum device and the other quantum devices.

In some embodiments, the computer-readable storage medium is configured to store program codes for performing the following steps: receiving a script verification request, wherein the script verification request carries a label of a quantum device requesting verification; determining, based on the label, a to-be-verified script corresponding to the quantum device requesting verification; and extracting the to-be-verified script and verifying the to-be-verified script to obtain a verification result.

In some embodiments, the computer-readable storage medium is configured to store program codes for performing the following steps: receiving a layout drawing instruction; and calling, in response to the layout drawing instruction, a third-party drawing application to draw the quantum chip layout.

In some embodiments, the computer-readable storage medium is configured to store program codes for performing the following steps: receiving a generation request for a quantum chip layout on a script interface; determining a quantum device type in response to the generation request, and displaying an original script corresponding to the quantum device type on the script interface, wherein a device parameter is defined in the original script; receiving a target value of the device parameter input on the script interface; receiving a layout generation instruction on the script interface; assigning, in response to the layout generation instruction, the target value to the device parameter to obtain a target script of a target quantum device corresponding to the quantum device type, and generating a quantum chip layout including the target quantum device based on the target script; and displaying the quantum chip layout on a predetermined display interface.

The embodiments may further be described using the following clauses:

1. A layout generation method, comprising:
determining a quantum device type;
acquiring an original script corresponding to the quantum device type, wherein a device parameter is defined in the original script;
acquiring a target value of the device parameter;
assigning the target value to the device parameter to obtain a target script of a target quantum device corresponding to the quantum device type; and
generating, based on the target script, a quantum chip layout comprising the target quantum device.

2. The method according to clause 1, wherein determining the quantum device type comprises:
acquiring a fuzzy structure of a quantum device; and
determining the quantum device type based on the fuzzy structure.

3. The method according to clause 1, wherein acquiring the original script corresponding to the quantum device type comprises:
acquiring a general-purpose script, wherein a type parameter of a device type is defined in the general-purpose script; and
assigning the quantum device type to the type parameter to obtain the original script corresponding to the quantum device type.

4. The method according to clause 1, wherein acquiring the target value of the device parameter comprises:
determining, when the device parameter comprises a geometric parameter and an action parameter, a geometric parameter type comprised in the geometric parameter and an action parameter type comprised in the action parameter respectively; and
acquiring a geometric parameter value corresponding to the geometric parameter type and an action parameter value corresponding to the action parameter type respectively, and using the geometric parameter value and the action parameter value as the target value.

5. The method according to clause 1, wherein when there are a plurality of quantum device types, the plurality of quantum device types correspond to a plurality of target quantum devices; and generating, based on the target script, the quantum chip layout comprising the target quantum device comprises:
acquiring an arrangement relationship between the plurality of target quantum devices; and
generating, based on target scripts of the plurality of target quantum devices and the arrangement relationship, the quantum chip layout comprising the plurality of target quantum devices.

6. The method according to clause 1, wherein generating, based on the target script, the quantum chip layout comprising the target quantum device comprises:
creating a target macro based on the target script, wherein the target macro is used for batch-generating other scripts of a plurality of other quantum devices of the same type as the target quantum device and having adjustable device parameters; and
generating, based on the target script and the target macro, the quantum chip layout comprising the target quantum device and the plurality of other quantum devices.

7. The method according to clause 6, wherein generating, based on the target script and the target macro, the quantum chip layout comprising the target quantum device and the plurality of other quantum devices comprises:
acquiring parameter values of the plurality of other quantum devices;
assigning the parameter values to device parameters of the corresponding other quantum devices through a parameter modification interface of the target macro, and batch-generating other scripts of the plurality of other quantum devices; and
generating, based on the target script and the other scripts, the quantum chip layout comprising the target quantum device and the plurality of other quantum devices.

8. The method according to clause 1, wherein after generating, based on the target script, a quantum chip layout comprising the target quantum device, the method further comprises:
receiving a script verification request, wherein the script verification request carries a label of a quantum device requesting verification;
determining, based on the label, a to-be-verified script corresponding to the quantum device requesting verification; and
extracting the to-be-verified script and verifying the to-be-verified script to obtain a verification result.

9. The method according to clause 1, further comprising:
receiving a layout drawing instruction; and
calling, in response to the layout drawing instruction, a third-party drawing application to draw the quantum chip layout.

10. The method according to any one of clause 1 to 9, wherein the quantum device comprises at least one of the following: Fluxonium quantum bits, a quantum port, a ground plane, a coplanar waveguide, or a quantum component constructed based on Fluxonium quantum bits.

11. A layout generation method, comprising:
receiving a generation request for a quantum chip layout on a script interface;
determining a quantum device type in response to the generation request, and displaying an original script corresponding to the quantum device type on the script interface, wherein a device parameter is defined in the original script;
receiving a target value of the device parameter input on the script interface;
receiving a layout generation instruction on the script interface;
assigning, in response to the layout generation instruction, the target value to the device parameter to obtain a target script of a target quantum device corresponding to the quantum device type;
generating, based on the target script, a quantum chip layout comprising the target quantum device; and
displaying the quantum chip layout on a predetermined display interface.

12. A layout generation apparatus, comprising:
a determination module configured to determine a quantum device type;
a first acquisition module configured to acquire an original script corresponding to the quantum device type, wherein a device parameter is defined in the original script;
a second acquisition module configured to acquire a target value of the device parameter;
an assignment module configured to assign the target value to the device parameter to obtain a target script of a target quantum device corresponding to the quantum device type; and
a generation module configured to generate, based on the target script, a quantum chip layout comprising the target quantum device.

13. A non-transitory computer readable medium that stores a set of instructions that is executable by one or more processors of an apparatus to cause the apparatus to perform operations according to any one of clauses 1 to 11.

14. A computer device, comprising
a memory configured to store instructions; and
one or more processors configured to execute the instructions to cause the apparatus to perform a layout generation method according to any one of clauses 1 to 11.

In some embodiments, a non-transitory computer-readable storage medium including instructions is also provided, and the instructions may be executed by a device, for performing the above-described methods. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same. The device may include one or more processors (CPUs), an input/output interface, a network interface, and/or a memory.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

It is appreciated that the above-described embodiments can be implemented by hardware, or software (program codes), or a combination of hardware and software. If implemented by software, it may be stored in the above-described computer-readable media. The software, when executed by the processor can perform the disclosed methods. The computing units and other functional units described in this disclosure can be implemented by hardware, or software, or a combination of hardware and software. One of ordinary skill in the art will also understand that multiple ones of the above-described modules/units may be combined as one module/unit, and each of the above-described modules/units may be further divided into a plurality of sub-modules/sub-units.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A layout generation method, comprising:
determining a quantum device type;
acquiring an original script corresponding to the quantum device type, wherein a device parameter is defined in the original script;
acquiring a target value of the device parameter;
assigning the target value to the device parameter to obtain a target script of a target quantum device corresponding to the quantum device type; and
generating, based on the target script, a quantum chip layout comprising the target quantum device.

2. The method according to claim 1, wherein determining the quantum device type comprises:
acquiring a fuzzy structure of a quantum device; and
determining the quantum device type based on the fuzzy structure.

3. The method according to claim 1, wherein acquiring the original script corresponding to the quantum device type comprises:
acquiring a general-purpose script, wherein a type parameter of a device type is defined in the general-purpose script; and
assigning the quantum device type to the type parameter to obtain the original script corresponding to the quantum device type.

4. The method according to claim 1, wherein acquiring the target value of the device parameter comprises:
determining, when the device parameter comprises a geometric parameter and an action parameter, a geometric parameter type comprised in the geometric parameter and an action parameter type comprised in the action parameter respectively;
acquiring a geometric parameter value corresponding to the geometric parameter type and an action parameter value corresponding to the action parameter type respectively; and
using the geometric parameter value and the action parameter value as the target value.

5. The method according to claim 1, wherein when there are a plurality of quantum device types, the plurality of quantum device types correspond to a plurality of target quantum devices, and generating, based on the target script, the quantum chip layout comprising the target quantum device comprises:
acquiring an arrangement relationship between the plurality of target quantum devices; and
generating, based on target scripts of the plurality of target quantum devices and the arrangement relationship, the quantum chip layout comprising the plurality of target quantum devices.

6. The method according to claim 1, wherein generating, based on the target script, the quantum chip layout comprising the target quantum device comprises:
creating a target macro based on the target script, wherein the target macro is used for batch-generating other scripts of a plurality of other quantum devices of the same type as the target quantum device and having adjustable device parameters; and
generating, based on the target script and the target macro, the quantum chip layout comprising the target quantum device and the plurality of other quantum devices.

7. The method according to claim 6, wherein generating, based on the target script and the target macro, the quantum chip layout comprising the target quantum device and the plurality of other quantum devices comprises:
acquiring parameter values of the plurality of other quantum devices;
assigning the parameter values to device parameters of corresponding other quantum devices through a parameter modification interface of the target macro;
batch-generating other scripts of the plurality of other quantum devices; and
generating, based on the target script and the other scripts, the quantum chip layout comprising the target quantum device and the plurality of other quantum devices.

8. The method according to claim 1, wherein after generating, based on the target script, the quantum chip layout comprising the target quantum device, the method further comprises:
receiving a script verification request, wherein the script verification request carries a label of a quantum device requesting verification;
determining, based on the label, a to-be-verified script corresponding to the quantum device requesting verification; and
extracting the to-be-verified script and verifying the to-be-verified script to obtain a verification result.

9. The method according to claim 1, further comprising:
receiving a layout drawing instruction; and
calling, in response to the layout drawing instruction, a third-party drawing application to draw the quantum chip layout.

10. The method according to claim 1, wherein the quantum device comprises at least one of the following: Fluxonium quantum bits, a quantum port, a ground plane, a coplanar waveguide, or a quantum component constructed based on Fluxonium quantum bits.

11. The method according to claim 1, wherein determining the quantum device type comprises:
receiving a generation request for a quantum chip layout on a script interface; and
determining the quantum device type in response to the generation request;
acquiring the original script corresponding to the quantum device type comprises:
displaying the original script corresponding to the quantum device type on the script interface;
acquiring the target value of the device parameter comprises:
receiving the target value of the device parameter input on the script interface;
assigning the target value to the device parameter to obtain the target script of the target quantum device corresponding to the quantum device type comprises:
receiving a layout generation instruction on the script interface; and
assigning, in response to the layout generation instruction, the target value to the device parameter to obtain the target script of the target quantum device corresponding to the quantum device type; and
after generating, based on the target script, the quantum chip layout comprising the target quantum device, the method further comprises:
displaying the quantum chip layout on a predetermined display interface.

12. A non-transitory computer readable medium that stores a set of instructions that is executable by one or more processors of an apparatus to cause the apparatus to perform operations comprising:
determining a quantum device type;
acquiring an original script corresponding to the quantum device type, wherein a device parameter is defined in the original script;
acquiring a target value of the device parameter;
assigning the target value to the device parameter to obtain a target script of a target quantum device corresponding to the quantum device type; and
generating, based on the target script, a quantum chip layout comprising the target quantum device.

13. The non-transitory computer readable medium according to claim 12, wherein the operations further comprise:
receiving a generation request for the quantum chip layout on a script interface;
determining the quantum device type in response to the generation request, and displaying an original script corresponding to the quantum device type on the script interface;
receiving the target value of the device parameter input on the script interface;
receiving a layout generation instruction on the script interface;
assigning, in response to the layout generation instruction, the target value to the device parameter to obtain the target script of a target quantum device corresponding to the quantum device type;
generating, based on the target script, the quantum chip layout comprising the target quantum device; and
displaying the quantum chip layout on a predetermined display interface.

14. The non-transitory computer readable medium according to claim 12, wherein the operations further comprise:
acquiring a fuzzy structure of a quantum device; and
determining the quantum device type based on the fuzzy structure.

15. The non-transitory computer readable medium according to claim 12, wherein the operations further comprise:
acquiring a general-purpose script, wherein a type parameter of a device type is defined in the general-purpose script; and
assigning the quantum device type to the type parameter to obtain the original script corresponding to the quantum device type.

16. The non-transitory computer readable medium according to claim 12, wherein the operations further comprise:
determining, when the device parameter comprises a geometric parameter and an action parameter, a geometric parameter type comprised in the geometric parameter and an action parameter type comprised in the action parameter respectively;
acquiring a geometric parameter value corresponding to the geometric parameter type and an action parameter value corresponding to the action parameter type respectively; and
using the geometric parameter value and the action parameter value as the target value.

17. An apparatus comprising:
a memory configured to store instructions; and
one or more processors configured to execute the instructions to cause the apparatus to perform operations for layout generation, wherein the operations comprise:
determining a quantum device type;
acquiring an original script corresponding to the quantum device type, wherein a device parameter is defined in the original script;
acquiring a target value of the device parameter;
assigning the target value to the device parameter to obtain a target script of a target quantum device corresponding to the quantum device type; and
generating, based on the target script, a quantum chip layout comprising the target quantum device.

18. The apparatus according to claim 17, wherein the operations further comprise:
receiving a generation request for the quantum chip layout on a script interface;
determining the quantum device type in response to the generation request, and displaying an original script corresponding to the quantum device type on the script interface;
receiving the target value of the device parameter input on the script interface;
receiving a layout generation instruction on the script interface;
assigning, in response to the layout generation instruction, the target value to the device parameter to obtain the target script of a target quantum device corresponding to the quantum device type;
generating, based on the target script, the quantum chip layout comprising the target quantum device; and
displaying the quantum chip layout on a predetermined display interface.

19. The apparatus according to claim 17, wherein the operations further comprise:
acquiring a fuzzy structure of a quantum device; and
determining the quantum device type based on the fuzzy structure.

20. The apparatus according to claim 17, wherein the operations further comprise:
acquiring a general-purpose script, wherein a type parameter of a device type is defined in the general-purpose script; and
assigning the quantum device type to the type parameter to obtain the original script corresponding to the quantum device type.
